(19) United States
(12) Patent Application Publication
(10) Pub. No.: US 2013/0063661 A1
(43) Pub. Date: Mar. 14, 2013

(54) PHASE SYNCHRONICATION CIRCUIT AND TELEVISION SIGNAL RECEPTION CIRCUIT

(71) Applicant: Masanori Toita, Miyagi-ken (JP)

(72) Inventor: Masanori Toita, Miyagi-ken (JP)

(21) Appl. No.: 13/605,675

(22) Filed: Sep. 6, 2012

(30) Foreign Application Priority Data
Sep. 8, 2011 (JP) 2011-196000

(51) Int. Cl. H03L 7/093

(52) U.S. Cl. 348/536; 327/157; 348/E05.009

(57) ABSTRACT

A phase synchronization circuit includes a low-pass filter configured to integrate the pulse signal output from a charge pump, and a line filter configured to be provided on a control voltage supply line for supplying the control voltage from the low-pass filter to a voltage controlled oscillation circuit. Here, one end of a capacitor of the line filter is connected, through resistance of a CP current switching circuit, from an output terminal of the charge pump to the ground in terms of high frequencies.

### CLAIM OF PRIORITY

This application claims benefit of Japanese Patent Application No. 2011-196000 filed on Sep. 8, 2011, which is hereby incorporated by reference in its entirety.

### BACKGROUND

1. Field of the Disclosure

The present disclosure relates to a phase synchronization circuit and a television signal reception circuit, which may apply a control voltage to a tuning line that is connected to a voltage controlled oscillation circuit for generating a local oscillation signal in accordance with the control voltage, and to an RF filter circuit for switching frequency characteristics by the control voltage.

2. Description of the Related Art

In the related art, a television signal reception circuit in which a control voltage is applied, through a tuning line, to an RF filter circuit provided in a reception system, and the RF filter circuit is set to frequency characteristics corresponding to a reception channel has been disclosed (For example, see Japanese Unexamined Patent Application Publication No. 2009-164745 and Japanese Unexamined Patent Application Publication No. 2001-203594). In the television signal reception circuit, a local oscillation signal for converting a reception RF signal into an intermediate frequency signal is input from a voltage controlled oscillation circuit to a mixer circuit provided in a post-stage of the RF filter circuit. The voltage controlled oscillation circuit is controlled by a control voltage supplied from a PLL circuit.

FIG. 4 is a schematic configuration diagram illustrating a PLL circuit provided in a television signal reception circuit and a tuning line portion. The PLL circuit illustrated in FIG. 4 inputs an oscillation signal generated by a crystal oscillator 101 to a frequency divider 102 to thereby convert the input oscillation signal into a reference oscillation signal. Meanwhile, the voltage controlled oscillation circuit (UHF/VHF oscillator) 100 in which an oscillation frequency is controlled by the control voltage feeds back, to a programmable frequency divider 103, the local oscillation signal that is output to the mixer circuit, and then performs a frequency-division on the fed back local oscillation signal. In the programmable divider 103, a frequency division ratio corresponding to the reception frequency is set. A phase comparator 104 outputs a phase error signal in accordance with a phase error between a reference oscillation signal output by the frequency divider 102 and a feedback signal output by the programmable frequency divider 103. A charge pump 105 converts the phase error signal input from the phase comparator 104 into a pulse signal to thereby output the pulse signal to a low-pass filter 106. The low-pass filter 106 integrates the pulse signal to convert the integrated pulse signal to a DC control voltage, and supplies the DC control voltage to the voltage controlled oscillation circuit 100 (for example, a VCO for UHF/VOC for VHF) through a control voltage supply line L.

As illustrated in FIG. 4, on a line through which the control voltage is applied from an output terminal of the low-pass filter 106 to the voltage controlled oscillation circuit 100 (VCO for UHF), a line filter 107 constituted of the low-pass filter is provided. The line filter 107 reduces a leakage level of a reference frequency (equivalent to 1/n of an original oscillation of a crystal vibrator) generated in the PLL circuit while securing excellent phase noise characteristics. The line filter 107 includes resistances R1 and R2 which are connected in series, and a capacitor C, which is connected between an intermediate connection point of the resistors R1 and R2 and the ground.

However, the capacitor C connected between the intermediate connection point of the resistors R1 and R2 and the ground has a characteristic in which capacity of the capacitor C is changed due to a difference in DC voltages (the control voltage) applied between terminals, and a characteristic (piezoelectric characteristic) in which the capacity is changed by mechanical shock. In a case in which the change in the DC voltage applied between the terminals of the capacitor C and the mechanical shock are simultaneously generated, an even larger capacity change is caused. As a result, a problem arises in that the line filter does not sufficiently exhibit a function as designed due to the change in the capacity of the capacitor C.

### SUMMARY

According to an aspect of the disclosure, there is provided a phase synchronization circuit which generates a control voltage for controlling an oscillation frequency of a voltage controlled oscillation circuit, and supplies the control voltage to the voltage controlled oscillation circuit, the phase synchronization circuit including: a charge pump configured to output a pulse signal in proportion to a phase error amount; a low-pass filter configured to integrate the pulse signal output from the charge pump to generate the control voltage; and a line filter configured to be provided on a control voltage supply line for supplying the control voltage from the low-pass filter to the voltage controlled oscillation circuit, wherein the low-pass filter includes a first capacitor of which one end is connected to an output terminal of the charge pump, and a parallel connection circuit of which one end is connected to the other end of the first capacitor and the other end is connected to the control voltage supply line and which includes a first resistor and a second capacitor connected in parallel to each other, wherein the line filter includes a second resistor of which one end is connected to the other end of the parallel connection circuit and the other end is connected to the control voltage supply line, and a third capacitor connected between the other end of the second resistor and the one end of the parallel connection circuit, and wherein one end of the third capacitor is connected, through the first capacitor, from the output terminal of the charge pump to the ground in terms of high frequencies.

According to the phase synchronization circuit of the invention, since both ends of the third capacitor that is a constituent component of the line filter are connected in terms of DC through the first resistor that is a component of the low-pass filter and the second resistor that is a component of the line filter, both electrodes of the third capacitor are nearly the same potential, so that no change in a potential difference applied to the third capacitor occurs (almost zero) even though the control voltage (synchronization voltage) is changed by a difference of reception channels, and a change in the capacity due to the applied voltage does not occur.

### BRIEF DESCRIPTION OF THE DRAWINGS

FIG. 1 is a configuration diagram illustrating a television signal reception circuit including a phase synchronization circuit according to an embodiment of the present invention;

FIG. 2 is a specific configuration diagram illustrating a PLL circuit and a line filter according to an embodiment of the invention;

FIG. 3 is a schematic diagram illustrating a line filter according to an embodiment of the invention; and

FIG. 4 is a schematic configuration diagram illustrating a PLL circuit and a tuning line portion according to the related art.

### DESCRIPTION OF THE EXEMPLARY EMBODIMENTS

Hereinafter, an embodiment of the invention will be described in detail with reference to the accompanying drawings.

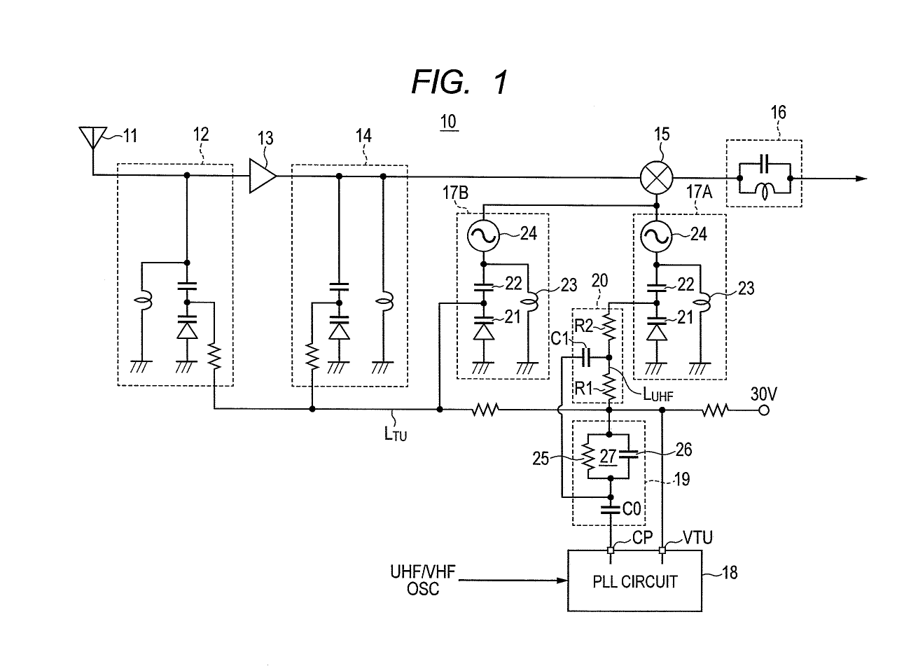

FIG. 1 is a configuration diagram illustrating a television signal reception circuit including a phase synchronization circuit according to an embodiment of the present invention. The television signal reception circuit 10 according to the present embodiment includes an antenna 11 that receives a broadcast wave that is a television signal, an antenna tuning circuit 12 that extracts a television reception signal (RF signal) from a reception signal (RF) output from the antenna 11, a high frequency amplifier 13 that amplifies the extracted television reception signal (RF signal), an RF tuning circuit 14 that extracts a desired band including a reception channel from the amplified television reception signal (RF signal), a mixer circuit 15 that frequency-converts the television reception signal (RF signal) extracted in the RF tuning circuit into an intermediate frequency signal (IF signal), an IF filter circuit 16 that extracts an IF signal from an output signal of the mixer circuit 15, and a post-stage circuit that processes the extracted IF signal to obtain a television signal.

In addition, the television signal reception circuit 10 according to the present embodiment further includes a voltage controlled oscillation circuit 17A that supplies a UHF receiving local oscillation signal to the mixer circuit 15, a voltage controlled oscillation circuit 17B that supplies a VHF receiving local oscillation signal to the mixer circuit 15, a PLL circuit 18 that generates a DC control voltage for controlling oscillation frequencies of the voltage controlled oscillation circuits 17A and 17B with respect to a tuning line L_{TU}, and controlling tuning voltages of the antenna tuning circuit 12 and the RF tuning circuit 14, and a low-pass filter 19 that integrates a pulse signal output from the PLL circuit 18 to output a DC control voltage.

The voltage controlled oscillation circuit 17A includes an LC resonance circuit of which a resonance frequency is changed by a control voltage which is constituted of a varactor diode 21 of a variable capacity element in which an anode is connected to the ground, a capacitor 22 of which one end is connected to a cathode of the varactor diode 21, and an inductor 23 connected in parallel to the varactor diode 21 and the capacitor 22, and includes an output circuit 24 that is oscillated by the resonance frequency of the LC resonance circuit to output a local oscillation signal. One end of a voltage supply line L_{UHF} is connected to the cathode of the varactor diode 21 of the LC resonance circuit.

The other voltage controlled oscillation circuit 17B is also configured in the same manner as that of the voltage controlled oscillation circuit 17A. In addition, the voltage supply line L_{UHF} is a part of the tuning line L_{TU}; however, in the present embodiment, a line filter 20 is provided on a line that supplies the control voltage to the voltage controlled oscillation circuit 17A, so that the name of the voltage supply line L_{UHF} is changed from that of the tuning line L_{TU}.

The low-pass filter 19 includes a capacitor C0 (a first capacitor), and a parallel circuit 27 constituted of a resistor 25 (a first resistor) and a capacitor 26 (a second capacitor) which are connected in parallel to each other. One end of the capacitor C0 is connected to a charge pump output terminal CP of the PLL circuit 18, and the other end of the capacitor C0 is connected to one end of the parallel circuit 27. The other end of the parallel circuit 27 is connected to the voltage supply line L_{UHF}.

In the present embodiment, the line filter 20 is provided on the voltage supply line L_{UHF} that supplies the control voltage from the low-pass filter 19 to the LC resonance circuit of the voltage controlled oscillation circuit 17A. The line filter 20 includes a resistor R1 (a second resistor) that is inserted in series into the voltage supply line L_{UHF}, a resistor R2, and a capacitor C1 (a third capacitor) in which one terminal is connected to an intermediate connection point between the resistor R1 and the resistor R2. In addition, a capacity value of the capacitor C1 is set as a sufficiently small value in comparison with the capacitor C0 of the low-pass filter 19. Both terminals of the capacitor C1 provided in the line filter 20 are connected in terms of DC through the resistor R1 of the line filter 20 and the resistor 25 of the low-pass filter 19 in series, so that both terminals of the capacitor C1 are maintained at the same voltage. Moreover, as will be described later, one end of the capacitor C1 that is a terminal of a side connected to the capacitor C0 is connected to the charge pump output terminal CP of the PLL circuit 18 through the capacitor C0, and then connected to the ground through a switch a resistor within the PLL circuit 18.

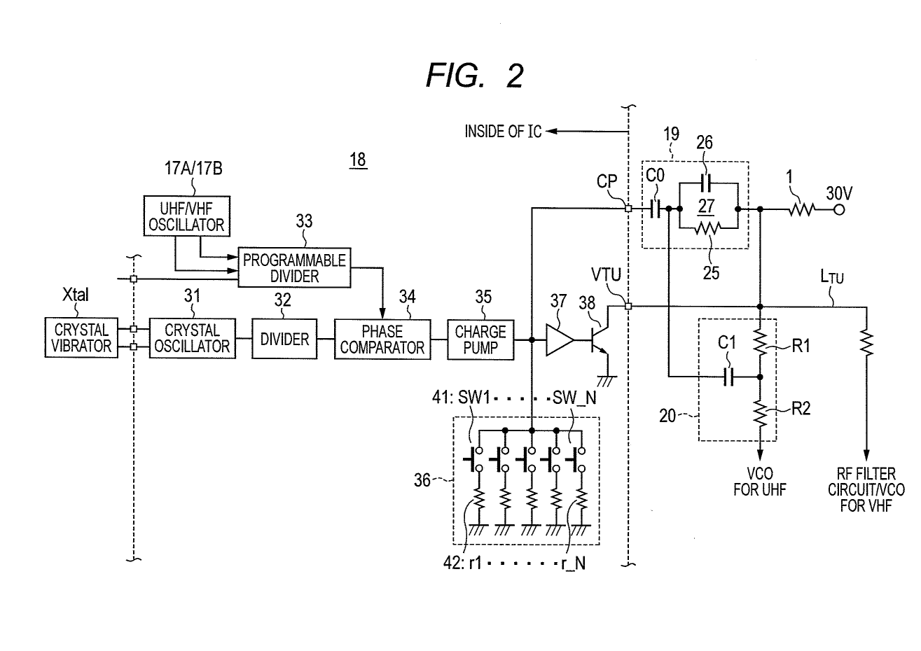

FIG. 2 is a specific configuration diagram illustrating the PLL circuit 18 and the line filter 20. The PLL circuit 18 includes a crystal oscillator 31 that oscillates a reference signal by taking an original oscillation signal from a crystal vibrator Xtal provided outside an IC, a frequency divider 32 that performs a 1/M-frequency division on the reference signal, and a programmable frequency divider 33 that may set a frequency division ratio (1/N) from an external CPU, and performs a 1/N-frequency division on the local oscillation signal which is fed back from the voltage controlled oscillation circuits 17A/17B (UHF/VHF oscillator). In addition, the PLL circuit 18 includes a phase comparator 34 that detects a phase difference error of each of the reference signals (1/M-frequency division) input from the frequency divider 32 and the local oscillation signal (1/N-frequency division) input from the programmable frequency divider 33 to thereby output a signal indicating a phase error amount, a charge pump 35 that converts into a positive or negative current pulse train in proportion to the phase error amount, a CP current switching circuit 36 that switches a charge pump current flowing in the charge pump 35 in accordance with a reception frequency, an operational amplifier 37 that amplifies an output signal of the charge pump 35, and a transistor 38 in which an output terminal of the operational amplifier 37 is connected to a base of the transistor 38 and a cathode is connected to the ground. An output terminal of the charge pump 35 is connected to the charge pump output terminal CP, and a collector of the transistor 38 is connected to an output terminal VTU. An input terminal of the low-pass filter 19 provided outside the IC is connected to the charge pump output terminal CP, and the tuning line L_{TD} provided outside the IC is connected to the output terminal VTU.

The CP current switching circuit 36 includes a switch group 41 constituted of a plurality of switches SW1 to SW_N provided in parallel, and a current setting resistor group 42 constituted of a plurality of resistors r1 to r_N provided between one end of each of the switches SW1 to SW_N and the ground. One terminal of each of the switches SW1 to SW_N is connected to the charge pump output terminal CP. The charge pump 35 switches a current (charge pump current) flowing to the charge pump 35 in accordance with the reception frequency so as to realize excellent channel selection characteristics in a wide band from a low frequency range to a high frequency range. The CP current switching circuit 36 is a control circuit used for switching the charge pump current flowing to the charge pump 35 in accordance with the reception frequency. In the CP current switching circuit 36, an arbitrary switch among the plurality of switches 41 is turned ON in accordance with the reception frequency, and the charge pump current flows through a resistor r (the third resistor) connected to the turned ON switch SW, so that it is possible to switch the charge pump current by selecting the turned ON switch SW.

Next, operations of the television signal reception circuit according to the present embodiment configured as above will be described.

First, overall operations of the television signal reception circuit will be described. In the television signal reception circuit 10, a television broadcast wave is received by the antenna 11, and an RF signal that is a reception signal is input to the mixer circuit 15 via the antenna tuning circuit 12, the high frequency amplifier 13, and the RF tuning circuit 14. A control voltage in accordance with the reception frequency is input to the antenna tuning circuit 12 and the RF tuning circuit 14 through the tuning line L_{TU}, so that frequency characteristics are set. In the mixer circuit 15, a local oscillation signal is multiplied with respect to an RF signal of a reception channel extracted in the RF tuning circuit 14 to thereby be converted into an IF signal. At the time of UHF band reception, the control voltage for controlling the oscillation frequency through the voltage supply line L_{UHF} in which the line filter 20 is provided is applied to the voltage controlled oscillation circuit 17A that supplies the local oscillation signal to the mixer circuit 15. At the time of VHF band reception, the local oscillation signal is supplied from the voltage controlled oscillation circuit 17B to the mixer circuit 15. The television broadcast signal of the reception channel which is converted into the IF signal in the mixer circuit 15 is output to the post-stage circuit through the IF filter circuit 16.

Next, operations relating to the PLL circuit 18 and the line filter 20 will be described.

The local oscillation signal output from the voltage controlled oscillation circuit 17A to the mixer circuit 15 is fed back to the programmable frequency divider 33. In the programmable frequency divider 33, a frequency division ratio (1/N) in accordance with the reception frequency is set at any time, and a signal obtained by performing a 1/N frequency division on the local oscillation signal is input to the phase comparator 34. In the frequency divider 32, a frequency division ratio corresponding to a reference frequency is set, so that a local oscillation signal capable of frequency-converting a reception frequency of a desired band into an intermediate frequency is supplied to the mixer circuit 15. The frequency divider 32 inputs, to the phase comparator 34, a frequency signal obtained by performing a frequency division on the reference frequency using the frequency division ratio corresponding to the reception frequency of the desired band. In the phase comparator 34, a phase difference between the frequency signal having performed the frequency division on the reference frequency and a current local oscillation signal (1/N-frequency division) is detected, and a phase error signal indicating a phase error amount is output to the charge pump 35. The charge pump 35 outputs a pulse signal in accordance with the phase error amount by receiving the phase error signal.

In this instance, in the charge pump 35, a charge pump current having a magnitude linked to the reception frequency flows so as to stabilize a circuit operation (channel selection operation). That is, the CP current switching circuit 36 turns ON the switch (combination of SW1 to SW_N) determined in advance in accordance with the reception frequency, so that the charge pump current flows to the ground through the current setting resistor (combination of r1 to r_N) connected to the turned ON switch (combination of SW1 to SW_N). In the present embodiment, the charge pump current is switched by the combination of the resistors r simultaneously connected to the ground.

The pulse signal output from the charge pump 35 is input from the charge pump output terminal CP to the low-pass filter 19, and the input pulse signal is integrated to be converted into a DC control voltage. As a result, a control voltage of a voltage value corresponding to the reception frequency is applied from the low-pass filter 19 to the tuning line L_{TU} and the voltage supply line L_{UHF}. In addition, by configuring the operational amplifier 37 and the transistor 38 in parallel in the low-pass filter 19, the low-pass filter 19 has a function of an active loop filter. Thus, by setting each constant of the low-pass filter 19, determination of a time constant, a phase margin, and transmission characteristics (the time constant and the phase margin) is performed so as to stably perform a control of the phase synchronization circuit (PLL) as well as a cut-off frequency. The low-pass filter 19 has the function of the active loop filter as described above, so that it is possible to supply a control voltage having a sufficient magnitude to the output terminal VTU.

For example, at the time of UHF band reception, the control voltage applied to the voltage supply line L_{UHF} is input to the voltage controlled oscillation circuit 17A through the line filter 20. In the voltage controlled oscillation circuit 17A, the capacity of the varactor diode 21 is changed by the control voltage applied to the voltage supply line L_{UHF}, so that a frequency of the local oscillation signal is switched. The local oscillation signal input from the voltage controlled oscillation circuit 17A to the mixer circuit 15 is fed back to the programmable frequency divider 33.

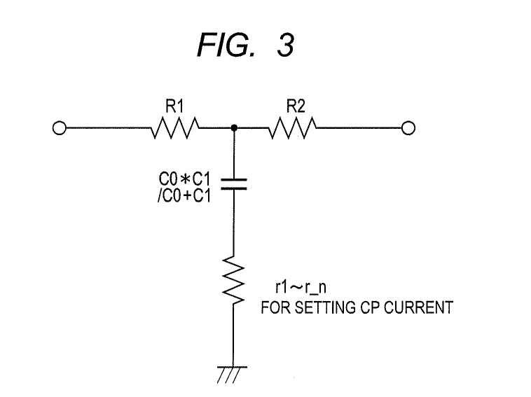

According to the present embodiment, the one end of the capacitor C1 provided in the line filter 20 is connected to the voltage supply line L_{UHF}, and the other end thereof is connected to an input side terminal (capacitor C0 side) of the parallel circuit 27 in the low-pass filter 19, so that the capacitor C1 is grounded through the current setting resistor r of the CP current switching circuit 36 provided inside the IC. Accordingly, the one end of the capacitor C1 is connected to the ground in terms of high frequencies, so that a T-type low-pass filter shown in FIG. 3 may be configured, and an original function of the line filter may be maintained.

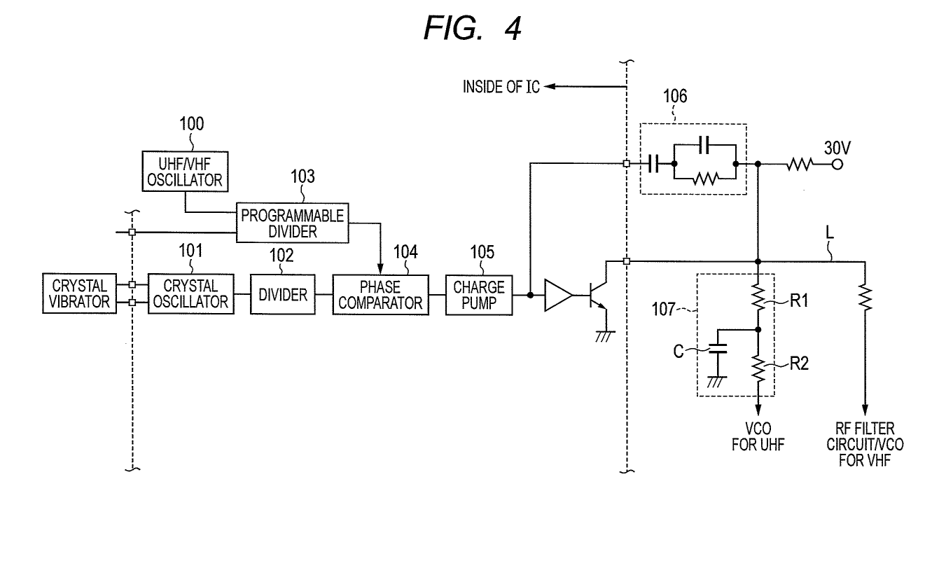

In addition, both ends of the capacitor C1 provided in the line filter 20 are directly connected to each other in terms of DC through the resistor 25 and the resistor R1, so that the same potential is applied to both ends of the capacitor C1, thereby preventing occurrence of noise due to the magnitude of a potential difference. As shown in FIG. 4, when a potential difference between the tuning line and GND is present, an expensive condenser having excellent piezoelectric resistant properties is necessary in a ground capacity (capacitor C); however, in the present embodiment, the expensive capacitor having excellent piezoelectric resistant properties is not necessary, thereby reducing costs.

In addition, according to the present embodiment, by the current switching function of the CP current switching circuit 36, connection with an amplifier unit including the low-pass filter 19 and the line filter 20 which are provided outside the IC and the operational amplifier 37 and the transistor 38 which are provided inside the IC is optimized by switching of the charge pump current, so that stabilization of the circuit operation may be promoted. In this instance, regarding the grounding of the capacitor C1 through the current setting resistor r, the resistor r set for the current setting has a characteristic of being linked to the reception frequency to be changed so as to stabilize the circuit operation (channel selection operation), so that a filter function of the line filter 20 using the resistor r may provide a new function of finely adjusting the frequency characteristics.

The invention is not limited to the above-described embodiments. For example, in the above description, the television signal reception circuit has been described; however, the invention may be applied to high frequency equipment including the PLL circuit in the same manner.

It should be understood by those skilled in the art that various modifications, combinations, sub-combinations and alterations may occur depending on design requirements and other factors insofar as they are within the scope of the appended claims of the equivalents thereof.

What is claimed is:

1. A phase synchronization circuit which generates a control voltage for controlling an oscillation frequency of a voltage controlled oscillation circuit, and supplies the control voltage to the voltage controlled oscillation circuit, the phase synchronization circuit, comprising:
a charge pump configured to output a pulse signal in proportion to a phase error amount;
a low-pass filter configured to integrate the pulse signal output from the charge pump to generate the control voltage; and
a line filter provided on a control voltage supply line that supplies the control voltage from the low-pass filter to the voltage controlled oscillation circuit, wherein
the low-pass filter includes a first capacitor of which one end is connected to an output terminal of the charge pump, and a parallel connection circuit of which one end is connected to the other end of the first capacitor and the other end is connected to the control voltage supply line and which includes a first resistor and a second capacitor connected in parallel to each other,
the line filter includes a second resistor of which one end is connected to the other end of the parallel connection circuit and the other end is connected to the control voltage supply line, and a third capacitor connected between the other end of the second resistor and the one end of the parallel connection circuit, and
one end of the third capacitor is connected, through the first capacitor, from the output terminal of the charge pump to the ground in terms of high frequencies.

2. The phase synchronization circuit according to claim 1, further comprising:
a charge pump current switching circuit including a third resistor connected between the output terminal of the charge pump and the ground, and that controls a charge pump current flowing to the charge pump by switching a resistance value of the third resistor,
wherein the one end of the third capacitor is connected, through the third resistor of the charge pump current switching circuit, to the ground in terms of high frequencies.

3. The phase synchronization circuit according to claim 2, wherein the resistance value of the third resistor is selected in accordance with the oscillation frequency of the voltage controlled oscillation circuit.

4. A television signal reception circuit comprising:
a phase synchronization circuit which generates a control voltage for controlling an oscillation frequency of a voltage controlled oscillation circuit, and supplies the control voltage to the voltage controlled oscillation circuit, the phase synchronization circuit, comprising:
a charge pump configured to output a pulse signal in proportion to a phase error amount;
a low-pass filter configured to integrate the pulse signal output from the charge pump to generate the control voltage;
a line filter provided on a control voltage supply line that supplies the control voltage from the low-pass filter to the voltage controlled oscillation circuit,
wherein the low-pass filter includes a first capacitor of which one end is connected to an output terminal of the charge pump, and a parallel connection circuit of which one end is connected to the other end of the first capacitor and the other end is connected to the control voltage supply line and which includes a first resistor and a second capacitor connected in parallel to each other,
wherein the line filter includes a second resistor of which one end is connected to the other end of the parallel connection circuit and the other end is connected to the control voltage supply line, and a third capacitor connected between the other end of the second resistor and the one end of the parallel connection circuit,
wherein one end of the third capacitor is connected, through the first capacitor, from the output terminal of the charge pump to the ground in terms of high frequencies;
wherein a charge pump current switching circuit including a third resistor is connected between the output terminal of the charge pump and the ground, and that controls a charge pump current flowing to the charge pump by switching a resistance value of the third resistor, and
wherein the one end of the third capacitor is connected, through the third resistor of the charge pump current switching circuit, to the ground in terms of high frequencies.

5. The television signal reception circuit according to claim 4, wherein the resistance value of the third resistor is selected in accordance with the oscillation frequency of the voltage controlled oscillation circuit.
